(19) United States
(12) Patent Application Publication
(10) Pub. No.: US 2006/0141686 A1
(43) Pub. Date: Jun. 29, 2006

(54) Copper gate electrode of liquid crystal display device and method of fabricating the same

(75) Inventors: Yu-Wei Liu, Shulin City (TW); Wen-Ching Tsai, Yilan County (TW); Kou-Yu Huang, Hsinchu County (TW); Hui-Fen Lin, Yunlin County (TW)

Correspondence Address: BACON & THOMAS, PLLC, 625 SLATERS LANE, FOURTH FLOOR, ALEXANDRIA, VA, 22314, US

(73) Assignee: AU OPTRONICS CORP., Hsin-Chu (TW)

(21) Appl. No.: 11/178,427

(22) Filed: Jul. 12, 2005

(30) Foreign Application Priority Data
Dec. 29, 2004 (TW) 93141256

(51) Int. Cl. H01L 21/84; H01L 21/4763

(52) U.S. Cl. 438/151; 438/158; 438/592

(57) ABSTRACT

A copper gate electrode, applied in a thin-film-transistor liquid crystal display (TFT-LCD) device, at least comprises an adhesive layer formed on a glass substrate, and a patterned copper layer formed on the adhesive layer. The adhesive layer at least comprises one of nitrogen and phosphorus (for example, polysilazane) for enhancing the electric characteristics of the LCD device.

This application claims the benefit of Taiwan application Serial No. 93141256, filed Dec. 29, 2004, the subject matter of which is incorporated herein by reference.

### BACKGROUND OF THE INVENTION

1. Field of the Invention

The invention relates in general to a copper gate electrode of liquid crystal display device and method of fabricating the same, and more particularly to the copper gate electrode and the method of fabricating the same for enhancing the electrical properties of an applied device.

2. Description of the Related Art

The thin film transistor liquid crystal displays (“TFT-LCD”), having the TFTs arranged in an array and the electrical components (i.e. capacitors, drivers), are capable of displaying the vivid images. With the advantages of handy size, light weight, low power consumption and no radiation contamination, the TFT-LCDs have been widely used in the world. In the commercial market, the TFT-LCD applications include the portable products such as personal digital assistants (PDA), regular size products such as monitors of laptop or desktop computers, and large size products such as 30″˜40″ LCD-TVs.

Conventionally, the gate electrode of the TFT-LCD is made of aluminum alloy. However, the material with higher conductivity is required for the larger-size and high-resolution TFT-LCD, to minimize the wire RC delay. The materials commonly used as the conductive wire include copper (Cu, electric resistance 1.7×10⁻⁶ Ωcm), aluminum (Al, electric resistance 2.6×10⁻⁶ Ωcm), titanium (Ti, electric resistance 41.6×10⁻⁶ Ωcm), Molybdenum (Mo, electric resistance 5.7×10⁻⁶ Ωcm), chromium (Cr, electric resistance 12.8×10⁻⁶ Ωcm) and nickel (Ni, electric resistance 6.8×10⁻⁶ Ωcm). Thus, aluminum alloy replaced by copper has been developed in the recent years.

FIG. 1 illustrates a cross-sectional view of a partial structure of a conventional TFT-LCD. A copper layer is sputtered on a transparent glass substrate 101, and the copper layer is etched to form a patterned copper layer (i.e. as the gate electrode of the TFT-LCD) 103 by photolithography. It is a need for the patterned copper layer 103 to have the appropriate taper angles in the sidewalls. Afterward, a silicon nitrite layer 105, an a-Si (amorphous silicon) layer 107 and an n+ a-Si layer 109 are laminated above the patterned copper layer 103.

Although copper possesses a good conductivity, the conventional process of fabricating the conductive wires (i.e. gate electrode) using copper still has several problems to be solved. For example, surface oxidization quickly occurs and it is not easy to control the taper angle of the patterned copper layer due to the difficulty of copper etch. The adhesion strength between the patterned copper layer 103 and the glass substrate 101 is weak, so is the adhesion between the patterned copper layer 103 and the silicon nitrite layer 105. If the patterned copper layer 103 directly contacts with the silicon nitrite layer 105, copper quickly reacts with silicon to produce Cu₃Si so as to change the electrical properties of the applied device (i.e. TFT-LCD), and copper diffused into the silicon nitrite layer 105 deteriorates the insulation property of silicon nitrite so as to increase the current leakage. Moreover, the bare patterned copper layer is reactive during the post-treatment such as plasma enhanced chemical vapor deposition (PECVD) or dry etching process; thus, it is easy to contaminate the processing machine so as to degrade the quality of the applied device.

Some attempts have been made for solving the problems listed above. The first attempt is to dispose at least one metal layer between the patterned copper layer 103 and the silicon nitrite layer 105 to solve the problems of weak adhesion, reactivity and diffusion between copper and silicon. The metal layer could be made of tantalum nitride (TaN)`titanium nitride (TiN)`aluminum nitride (AlN)`aluminum oxide (Al₂O₃)`titanium oxide (TiO₂)`tantalum (Ta)`molybdenum (Mo)`chromium (Cr)`titanium (Ti)`tungsten (W) and nickel (Ni). However, additional steps such as deposition, developing and etching are required for forming this metal layer. The second attempt is to use the copper alloy such as an alloy of copper and chromium (Cu₁₋ₓCrₓ), or an alloy of copper and magnesium (Cu₁₋ₓMgₓ) as the material of the patterned copper layer 103. Also, the thermal oxidation is applied to form chromium oxide (Cr₂O₃) or magnesium oxide (MgO) on the surface of the patterned copper layer 103 for solving the problems of weak adhesion, reactivity and diffusion between copper and silicon. Similarly, the second attempt requires extra steps such as metal deposition, developing, etching and thermal oxidation during the fabrication. The third attempt is to dispose an ITO (indium tin oxide) layer between the patterned copper layer 103 and the transparent glass substrate 101 for solving the problem of weak adhesion between the copper and glass.

Moreover, the improper taper angle of patterned copper layer causes the impact of film coverage of post processes, and therefore the yield of production is decreased. The three attempts discussed above cannot control the taper angle of patterned copper layer; a need still exists for a method of obtaining a proper taper angle.

### SUMMARY OF THE INVENTION

It is therefore an object of the invention to provide a copper gate electrode of liquid crystal display device and method of fabricating the same. By applied a polymer layer comprising at least one of nitrogen and phosphorus as an adhesion layer formed between the glass substrate and the patterned copper layer, the electrical properties of the applied product are thus enhanced.

The invention achieves the objects by providing a copper gate electrode applied in a thin film transistor liquid crystal displays (TFT-LCD). The copper gate electrode at least comprises an adhesion layer formed on a glass substrate, and a patterned copper layer formed on the adhesion layer. The adhesion layer comprises at least one of nitrogen and phosphorus.

The invention achieves the objects by providing a method of fabricating copper gate electrode, comprising steps of providing a glass substrate; forming an adhesion layer on the glass substrate; forming a copper layer on the adhesion layer; and defining the copper layer to form a patterned copper layer. The adhesion layer, comprising at least one of nitrogen and phosphorus, could be formed by a spin coating method. The thickness of the adhesion layer ranges from about 100 nm to about 3000 nm.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1 (related art) illustrates a cross-sectional view of a partial structure of a conventional TFT-LCD.

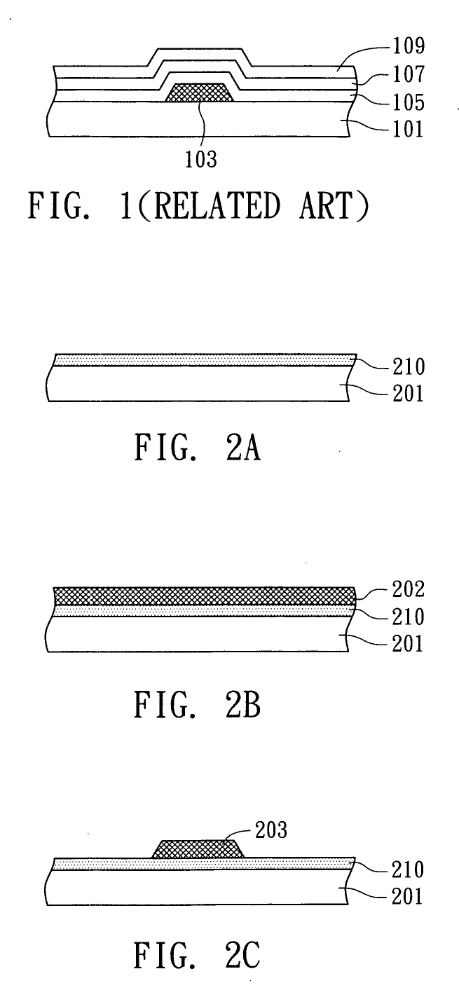

FIG. 2A˜FIG. 2E illustrate a partial process for fabricating a TFT-LCD according to the first embodiment of the invention.

FIG. 3A˜FIG. 3F illustrate a partial process for fabricating a TFT-LCD according to the second embodiment of the invention.

### DETAILED DESCRIPTION OF THE INVENTION

In the present invention, a polymer layer comprising at least one of nitrogen and phosphorus is formed between the glass substrate and the patterned copper layer as an adhesion layer, thereby solving the problem of weak adhesion between glass and copper. The TFT-LCD possesses excellent electrical properties while applied with the adhesion layer of the present invention.

The first and second embodiments disclosed herein are for illustrating the invention, but not for limiting the scope of the invention. Additionally, the drawings used for illustrating the embodiments of the invention only show the major characteristic parts in order to avoid obscuring the invention. Accordingly, the specification and the drawings are to be regard as an illustrative sense rather than a restrictive sense.

### FIRST EMBODIMENT

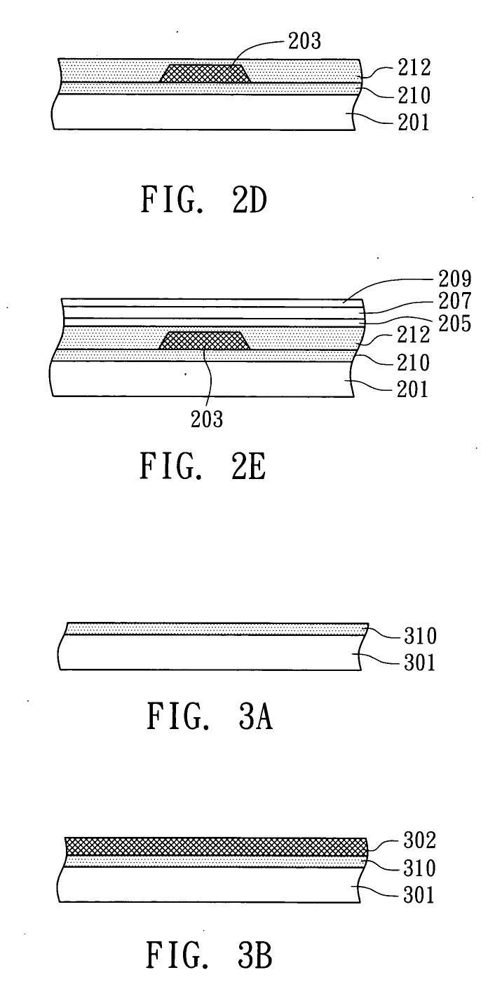

FIG. 2A˜FIG. 2E illustrate a partial process for fabricating a TFT-LCD according to the first embodiment of the invention. First, a glass substrate 201 pre-cleaned by deionized water is provided. An adhesion layer 210 is formed on the glass substrate 201, as shown in FIG. 2A. The technique of spin coating or spinless coating could be used in the formation of the adhesion layer 210. The material of the adhesion layer 210 is the polymer comprising at least one of nitrogen and phosphorus, such as polysilane (with high transparency and thermal stability), photosensitive methylsilazane (PS-MSZ) and non-photosensitive MSZ (available from Clariant Cop.) The thickness of the adhesion layer 210 ranges from about 100 nm to about 3000 nm.

Then, a copper layer 202 is formed (e.g. sputtered) on the adhesion layer 210, as shown in FIG. 2B. The copper layer 202 is then defined (i.e. patterned) by photolithography. For example, a photo-resist (PR) layer is formed above the copper layer 202, and the PR layer is exposed and developed to form a PR pattern. The copper layer 202 is then etched according to the PR pattern to form a patterned copper layer 203; finally, the PR pattern is stripped, as shown in FIG. 2C. In the applied product (e.g. TFT-LCD), the patterned copper layer 203 could be formed as the gate electrode.

Afterward, a barrier layer could be preferably formed on the patterned copper layer 203, for the purpose of preventing the patterned copper layer from contamination in the sequential processes. With the barrier layer, the possibility of the processing machine contaminated by copper also can be greatly decreased in the dry-etching condition. As shown in FIG. 2D, a barrier layer 212 is formed on the patterned copper layer 203 in the first embodiment. The technique of spin coating or spinless coating could be used in the formation of the barrier layer 212. The material of the barrier layer 212 is the polymer comprising at least one of nitrogen and phosphorus, such as polysilane (with high transparency and thermal stability), photosensitive methylsilazane (PS-MSZ) and non-photosensitive MSZ (available from Clariant Cop.) The thickness of the barrier layer 212 is preferably ranged from 500 nm to 3000 nm.

The sequential processes such as formation of a silicon nitrite layer 205, an a-Si (amorphous silicon) layer 207 and a n+ a-Si layer 209 are performed to stack above the barrier layer 212, as shown in FIG. 2E.

### SECOND EMBODIMENT

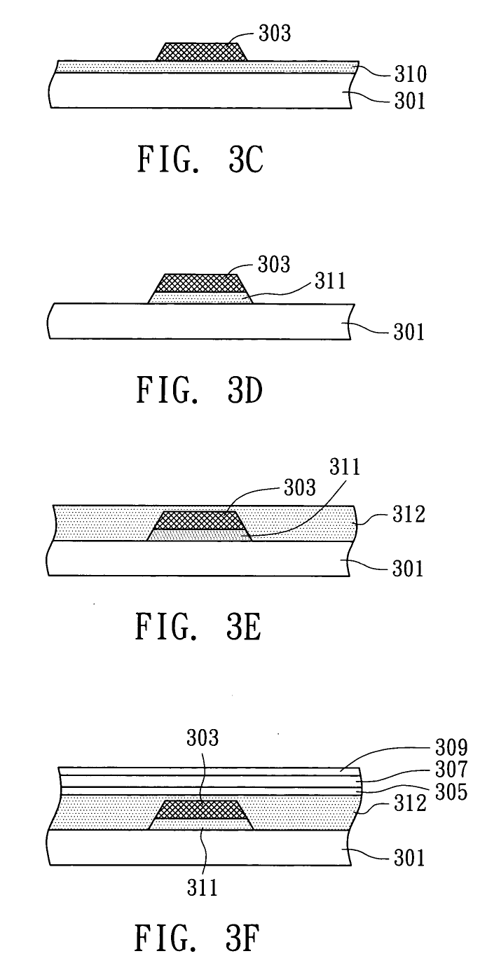

FIG. 3A˜FIG. 3F illustrate a partial process for fabricating a TFT-LCD according to the second embodiment of the invention. First, a glass substrate 301 pre-cleaned by deionized water is provided. Then, an adhesion layer 310 is formed on the glass substrate 301, as shown in FIG. 3A. The technique of spin coating or spinless coating could be used in the formation of the adhesion layer 310. The material of the adhesion layer 310 is the polymer comprising at least one of nitrogen and phosphorus, such as polysilane (with high transparency and thermal stability), photosensitive methylsilazane (PS-MSZ) and non-photosensitive MSZ (available from Clariant Cop.) The thickness of the adhesion layer 310 ranges from about 100 nm to about 3000 nm.

Then, a copper layer 302 is formed (e.g. sputtered) on the adhesion layer 310, as shown in FIG. 3B. The copper layer 302 is patterned by photolithography. For example, a photo-resist (PR) layer is formed above the copper layer 302, and the PR layer is exposed and developed to form a PR pattern. The copper layer 302 is then etched according to the PR pattern to form a patterned copper layer 303; finally, the PR pattern is stripped, as shown in FIG. 3C.

Next, the adhesion layer 310 is patterned (e.g. dry-etched) according to the patterned copper layer 303, and a patterned adhesion layer 311 is thus formed as shown in FIG. 3D.

Afterward, a barrier layer 312 could be preferably formed on the patterned copper layer 303, as shown in FIG. 3D. The technique of spin coating or spinless coating could be used in the formation of the barrier layer 312. The material of the barrier layer 312 is the polymer comprising at least one of nitrogen and phosphorus, such as polysilane (with high transparency and thermal stability), photosensitive methylsilazane (PS-MSZ) and non-photosensitive MSZ (available from Clariant Cop.) The thickness of the barrier layer 312 ranges from about 500 nm to about 3000 nm.

The sequential processes such as formation of a silicon nitrite layer 305, an a-Si (amorphous silicon) layer 307 and a n+ a-Si layer 309 are performed to stack above the barrier layer 312, as shown in FIG. 3F.

According to the aforementioned embodiments, the adhesion layer comprising at least one of nitrogen and phosphorus is applied to solve the problems, particularly the problem of weak adhesion between the glass and copper, so as to enhance the adhesion strength between the glass substrate and the patterned copper layer.

While the invention has been described by way of examples and in terms of the preferred embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A copper gate electrode for a thin film transistor liquid crystal display (TFT-LCD), comprising:
an adhesion layer formed on a substrate; and
a patterned copper layer formed on the adhesion layer;
wherein the adhesion layer comprises at least one of nitrogen and phosphorus.

2. The copper gate electrode according to claim 1, wherein the adhesion layer is substantially made of photosensitive methylsilazane (PS-MSZ).

3. The copper gate electrode according to claim 1, wherein the adhesion layer is substantially made of non-photosensitive methylsilazane.

4. The copper gate electrode according to claim 1, wherein a thickness of the adhesion layer ranges from about 100 nm to about 3000 nm.

5. The copper gate electrode according to claim 1, further comprising a barrier layer formed on the patterned copper layer.

6. The copper gate electrode according to claim 5, wherein the barrier layer is substantially made of photosensitive methylsilazane (PS-MSZ).

7. The copper gate electrode according to claim 5, wherein the barrier layer is substantially made of non-photosensitive methylsilazane.

8. The copper gate electrode according to claim 5, wherein a thickness of the barrier layer ranges from about 500 nm to about 3000 nm.

9. The copper gate electrode according to claim 5, further comprising a silicon nitrite layer, an amorphous silicon (a-Si) layer and an n+ a-Si layer laminated over the barrier layer.

10. A method for fabricating a copper gate electrode, comprising the steps of:
providing a substrate;
forming an adhesion layer on the substrate;
forming a copper layer on the adhesion layer; and
patterning the copper layer to form a patterned copper layer;
wherein the adhesion layer comprises at least one of nitrogen and phosphorus.

11. The method according to claim 10, wherein the adhesion layer is formed by spin coating.

12. The method according to claim 10, wherein a thickness of the adhesion layer ranges from about 100 nm to about 3000 nm.

13. The method according to claim 10, wherein the adhesion layer is substantially made of polysilane.

14. The method according to claim 10, wherein the copper layer is formed by sputtering.

15. The method according to claim 10, wherein patterning the copper layer to form the patterned copper layer comprising:
forming a photo-resist layer on the copper layer;
exposing and developing the photo-resist layer to form a photo-resist (PR) pattern;
etching the copper layer according to the PR pattern; and
removing the PR pattern.

16. The method according to claim 15, wherein the adhesion layer is defined according to the PR pattern after the copper layer is etched, so as to form the patterned copper layer and a patterned adhesion layer.

17. The method according to claim 10, further comprising the step of:
forming a barrier layer on the patterned copper layer.

18. The method according to claim 17, wherein a thickness of the barrier layer ranges from about 500 nm to about 3000 nm.

19. The method according to claim 17, wherein the barrier layer is substantially made of polysilane.
